(19) United States
(12) Patent Application Publication
(10) Pub. No.: US 2011/0151590 A1
(43) Pub. Date: Jun. 23, 2011

(54) APPARATUS AND METHOD FOR LOW-K DIELECTRIC REPAIR

(75) Inventors: James D. Carducci, Sunnyvale, CA (US); Srinivas D. Nemani, Sunnyvale, CA (US); Hairong Tang, San Jose, CA (US); Hui Sun, Xian (CN); Igor Markovsky, San Jose, CA (US); Ezra R. Gold, Sunnyvale, CA (US); Iwalani S. Kaya, Santa Clara, CA (US); Ellie Y. Yieh, San Jose, CA (US); Chunlei Zhang, Santa Clara, CA (US); Kenneth S. Collins, San Jose, CA (US); Michael D. Armacost, San Jose, CA (US); Ajit Balakrishna, Sunnyvale, CA (US); Thorsten B. Lill, Santa Clara, CA (US)

(73) Assignee: Applied Materials, Inc., Santa Clara, CA (US)

(21) Appl. No.: 12/846,664

(22) Filed: Jul. 29, 2010

Related U.S. Application Data
(60) Provisional application No. 61/231,653, filed on Aug. 5, 2009.

(51) Int. Cl. H01L 21/00; C23C 16/50; H01L 21/465

(52) U.S. Cl. 438/4; 118/726; 118/723 R; 156/345.51; 257/E21.001

(57) ABSTRACT

A method, a system and a computer readable medium for integrated in-vacuo repair of low-k dielectric thin films damaged by etch and/or strip processing. A repair chamber is integrated onto a same platform as a plasma etch and/or strip chamber to repair a low-k dielectric thin film without breaking vacuum between the damage event and the repair event. UV radiation may be provided on the integrated etch/repair platform in any combination of before, after, or during the low-k repair treatment to increase efficacy of the repair treatment and/or stability of repair.

### CLAIM OF PRIORITY

This application is related to, and claims priority to, the provisional utility application entitled “APPARATUS AND METHOD FOR LOW-K DIELECTRIC REPAIR,” filed on Aug. 5, 2009, having an application number of 61/231,653 and herein incorporated by reference in its entirety for all purposes.

### BACKGROUND

1) Field

The invention is in the field of Semiconductor Processing and more particularly relate to repair of low-k/ultra low-k dielectric materials which have been damaged by prior plasma processing.

2) Description of Related Art

Dielectric materials with an effective dielectric constant (k) below about 2.5, commonly referred to as “ultra low-k” materials, become extremely important to integrated circuit performance beyond the 45 nm technology node. Generally, these ultra low-k materials, referred to herein as simply “low-k,” have increased porosity relative to materials having a k-value in the 2.5 to 3.0 range. However, carbon depletion of these porous films during plasma etching and ashing processes is known to lead to subsequent moisture uptake which detrimentally increases the capacitance and leakage current of the film. This surface hydrophilisation phenomena generally referred to as plasma damage hinders the further scaling of low-k material development as it posses significant integration problems.

### SUMMARY

Disclosed herein are embodiments of methods and a systems for integrated, in-vacuo low-k dielectric thin film repair with the ability to restore k-values (e.g., reduce k-values to an “as-deposited” level) of a low-k dielectric film increased as a result of exposing portions (e.g., sidewalls of a via made in the low-k dielectric thin film) to various plasma processes (e.g., halogen etching plasmas, oxidizing/reducing cleaning plasmas, etc.) performed by one or more chamber on a multi-chambered mainframe platform. More specifically, the methods and systems may replenish carbon (e.g., in the form of organic groups) within a surface skin thickness of the low-k dielectric which is lost from the low-k dielectric film as a result of process exposure to reduce the k-value of the low-k dielectric toward the “as-deposited” k-value and in many cases yield a post-repair k-value below 2.5. The methods and systems may repair a substantial portion of the low-k dielectric damaged surface layer in a substantially isotropic manner without breaking vacuum from the time at which the damaging plasma processing is performed until subsequent to the low-k repair.

Embodiments of the methods and system disclosed herein may incorporate organic surface groups into the carbon-depleted surface layer of the low-k film to render a surface more hydrophobic (e.g., convert a hydrophilic surface to a hydrophobic surface). Embodiments of the methods and systems disclosed herein may also prevent compromise of critical dimension (e.g., the smallest separation of layers, features). Embodiments include methods for chemically repairing surfaces of low-k interlayer dielectric (ILD) thin film materials following certain semiconductor processing operations. By exposing ILD surfaces damaged by such processing operations to, for example, a silane incorporation agent, the damaged ILD surface can be chemically repaired before exposure to ambient moisture, subsequent wet cleans, etc. The repaired ILD surface may then be protected from subsequent processing steps and maintain a low-k value below 2.5.

In one exemplary embodiment, a plasma processing platform for integrated in-vacuo repair of plasma-damaged low-k dielectric thin films includes both a plasma etch chamber module and a low-k repair chamber module coupled to a mainframe transport module to transport a workpiece first etched in the plasma etch chamber module to the low-k repair chamber under vacuum. The low-k repair chamber is operated under vacuum and includes a pedestal to support the workpiece with chamber walls surrounding the pedestal. In addition to the low-k repair chamber, the low-k repair module includes a vapor cabinet mechanically coupled to the repair chamber by a support frame. The vapor cabinet contains a flash vaporizer coupled to a carrier gas mass flow controller (MFC) through which a carrier gas may be provided to the chamber. The flash vaporizer is further coupled to a low-k repair liquid chemical flow meter (LFM) through which a liquid repair chemistry may be provided to the chamber. A gas stick couples the flash vaporizer to the low-k repair chamber to inject a vapor-phase chemical into the repair chamber as a chemical low-k repair treatment.

In embodiments, the pedestal, the chamber walls, and the gas stick are controllable to a temperature of at least 60° C. to prevent condensation of the repair chemistry in the low-k repair module components.

In further embodiments, the low-k repair module may further include a UV radiation source external to the repair chamber to perform a UV treatment of the workpiece before, during or concurrently with the chemical low-k repair treatment. For some embodiments which utilize UV radiation source external to the repair chamber, a portion of the chamber walls may be of a UV transparent material, such as quartz. In some of these embodiments, the gas stick may couple into the chamber walls at a position proximate to an outer edge of the workpiece to avoid shadowing the UV radiation. In certain of these embodiments, the pedestal is rotatable to improve uniformity of the low-k repair chemical input into the chamber at a position proximate to an outer edge of the workpiece.

In some embodiments, the low-k repair module may also operated as a plasma resist strip chamber prior to performing the UV and/or chemical low-k repair treatments. For such embodiments, the low-k repair module further includes a plasma power source and a oxidative process gases, such as O₂ and/or CO₂.

In certain embodiments, the gas stick is coupled with a showerhead. The showerhead may be of a material having a high thermal conductivity, such as a metal like bare aluminum so that the showerhead may be passively heated to at least 60° C. via heating of the chamber walls.

Embodiments include methods for repair of plasma-damaged low-k dielectric thin films. In one exemplary embodiment, a workpiece is loaded into a multi-chamber vacuum processing platform. A low-k film, for example having a dielectric constant below 2.5, is exposed to an etching plasma in an etch chamber of the platform to pattern a layer on the workpiece. The workpiece is then transported, under vacuum, from the etch chamber to a low-k repair chamber of the platform. In the low-k repair chamber a UV treatment of the low-k dielectric film is performed by exposing the workpiece to UV radiation source external to the low-k repair chamber. In the low-k repair chamber, a silylation treatment of the low-k dielectric film is performed by exposing the workpiece to a vapor phase low-k repair chemistry at sub-atmospheric pressures while the workpiece is at an elevated temperature before the workpiece is unloaded from the vacuum processing platform.

### BRIEF DESCRIPTION OF THE DRAWINGS

FIG. 1A depicts a flow diagram for methods of integrated low-k dielectric film repair, in accordance with embodiments of the present invention;

FIG. 1B depicts a operations in low-k dielectric film treatment, in accordance with embodiments of the present invention;

FIG. 2 depicts a plan view of a multi-chambered processing apparatus including an etch chamber and a low-k dielectric film repair chamber on a same mainframe platform, in accordance with embodiments of the present invention;

FIGS. 3A and 3B depict a cross-sectional and plan view of a schematic of a low-k dielectric film repair chamber, in accordance with an embodiment of the present invention;

FIGS. 3C and 3D depict a cross-sectional and plan view of a schematic of a low-k dielectric film repair chamber, in accordance with another embodiment of the present invention;

FIG. 4A depicts an isometric view of a low-k dielectric repair module exterior, in accordance with the embodiment depicted in FIGS. 3A and 3B;

FIG. 4B depicts an isometric view of a low-k dielectric repair module interior, in accordance with the embodiment depicted in FIG. 4A;

FIG. 5 depicts a schematic of a liquid chemistry deliver system for a low-k dielectric repair chamber, in accordance with an embodiment of the present invention; and

FIG. 6 depicts a block diagram of the liquid chemistry deliver system of FIG. 5, in accordance with an embodiment of the present invention; and

FIG. 7 depicts a block diagram of a computer processing system for automated control of methods of integrated low-k dielectric film repair, in accordance with embodiments of the present invention.

### DETAILED DESCRIPTION

Embodiments of systems and methods for repair of low-k, porous, silicon-based dielectric thin films are described herein. In the following description, numerous specific details are set forth, such as order of operations, in order to provide a thorough understanding of the present invention. It will be apparent to one skilled in the art that the present invention may be practiced without these specific details. In other instances, well-known features, such as specific process recipes and equipment components, are not described in detail in order to not unnecessarily obscure the present invention. Furthermore, it is to be understood that the various embodiments shown in the Figures are merely illustrative representations and are not necessarily drawn to scale.

The extent of such carbon incorporation/repair of a low-k film may be characterized through electron energy loss spectroscopy (EELS), transmission electron microscopy (TEM), electrical capacitance and leakage measurements, as well as any other measurement technique known to be able to detect and/or measure damage of low-k films which correlates to increased k value and/or reduced dielectric strength. Additionally, though specific embodiments of systems and methods are discussed with reference to specific hardware and chemistries, one skilled in the art will realize that an aspect of the invention is also the synergy between processes and hardware more than application of either alone.

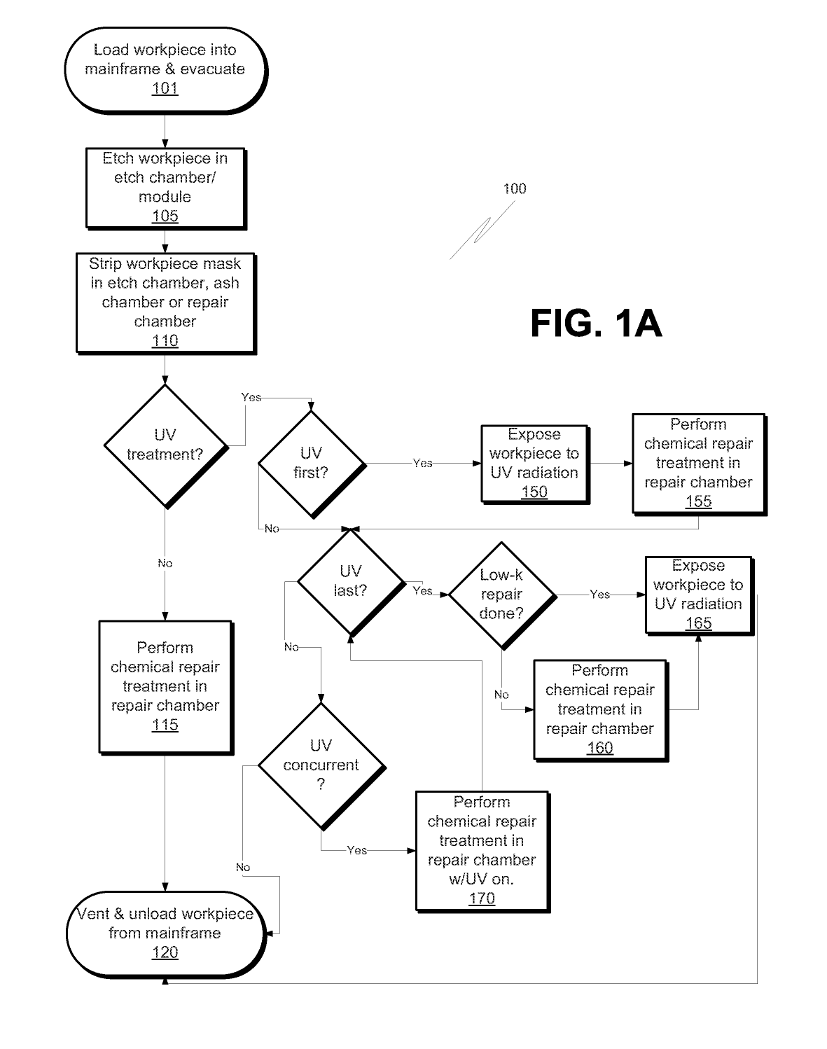

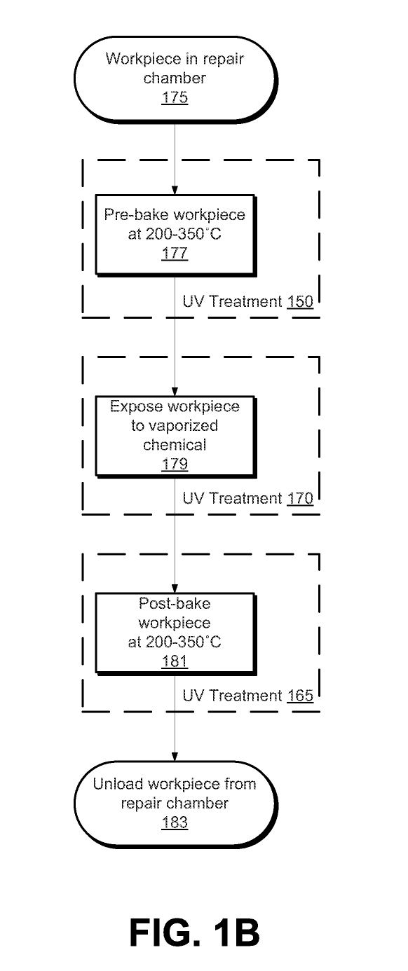

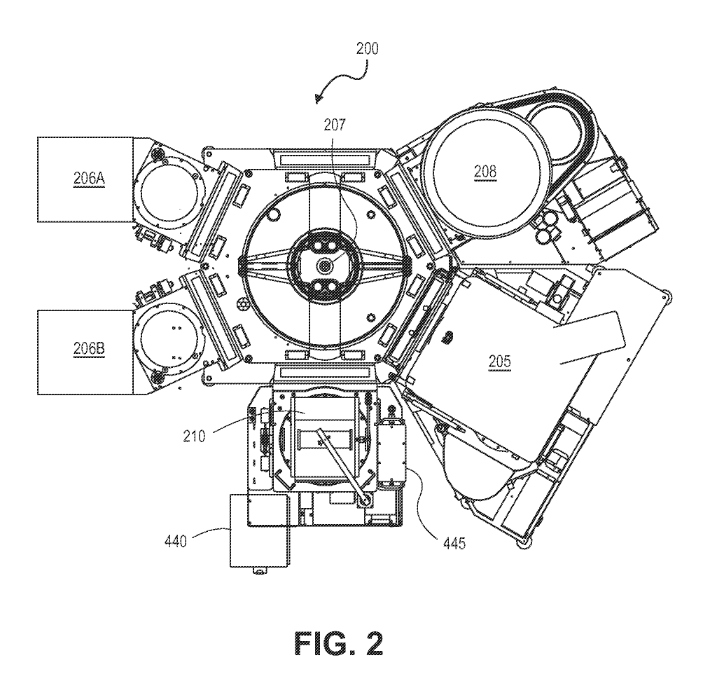

As shown in FIG. 1A, an embodiment of the method includes loading a first workpiece (e.g., a semiconductor wafer having IC at various states of formation thereon) into a plasma processing platform at operation 101. The plasma processing platform may be any conventional platform know in the art which includes an evacuated mainframe couple to a vacuum (e.g., sub-atmospheric) processing module which energizes a plasma source to process the workpiece. As one example, a platform 200 is depicted in FIG. 2. The platform 200 may be, for example, an Enabler platform commercially available from Applied Materials, Inc. of Santa Clara Calif. and may be coupled to a dielectric etch chamber 205, such as any of the eMax, Enabler, or Producer etch chambers commercially available from Applied Materials. Of course, other platform/chamber combinations may also be utilized to practice embodiments of the present invention. In the particular embodiment depicted in FIG. 2, a workpiece is loaded from an indexer 206A, evacuated to sub-atmospheric pressure, and loaded into the mainframe transport module 207.

In an embodiment, the workpiece includes a low-k dielectric thin film layer which is masked to be etched by the etch chamber on the mainframe to form trenches and/or vias into the low-k dielectric thin film layer. The low-k dielectric thin film layer to be etched may be any conventional porous, low-k, silicon based dielectric materials having a k below about 2.5, such as, but not limited to, carbon-doped silicon, also known as organosilicate glass (OSG). OSG films have a Si_{w}CₓO_{y}H_{z} structure wherein tetravalent silicon has a variety of organic group substitutions. The most common substitution is a methyl (CH₃) group provided by an organic precursor gas like trimethylsilane or tetramethylsilane (“3MS” and “4MS” respectively). In OSG, the amorphous SiO₂ network is sporadically interrupted by the organic group, decreasing the density of the film and introducing Si—C bonds which are relatively less polar, both of which decrease the film dielectric constant.

In a particular embodiment, the OSG is BDII (BlackDiamond II), also commercially available from Applied Materials, Inc. BDII is a particular example of a PECVD OSG which, depending on deposition parameters has a k-value between about 2.25 and 2.5 and is generally distinguished from spin-on OSGs because different methods of formation result in different material properties. In particular, the pore dimensions between PECVD OSG and spin-on OSG can be markedly different with PECVD OSG having micro pores having diameters in the range of 0.5 to 3 nm and spin-on OSG typically having meso pores with diameters in the range of 10-20 nm. It has been found that PECVD OSG having a k-value of about 2.4 provides a particularly good response to the repair apparatus and repair techniques described herein and while such may be readily adapted to other low-k films, such as spin-on OSG and other spin-on materials, the low-k repair performance may not prove as advantageous as the preferred PECVD OSG embodiment for providing a post-plasma processed low-k film with a k-value no greater than 2.5.

In addition to OSG, nanofoams are another class of exemplary low-k thin film dielectric materials which incorporate voids or pores in their structure as localized absences of material and this class of materials may also be repairable with the apparatus and method(s) described herein. Such materials are typically characterized as very porous (80-99%) and with pores of 10 nm in diameter or greater. In still other embodiments, the workpiece includes a spin-on low-k thin film dielectric layer based on hydrosilesquioxane (“HSQ”) and methylsilesquioxane (“MSQ”).

At operation 105 (FIG. 1A), the workpiece is etched in the plasma etch chamber 205 (FIG. 2). For example, a via and/or trench is formed in the low-k dielectric thin film layer with a plasma of any conventional process gas, such as, but not limited to fluorocarbons, halocarbons and oxidants. At operation 110, any masking materials and/or residues from the etch process which are left on the workpiece following the etch operation 105 are stripped from the workpiece. Depending on equipment utilization factors, operation 110 may be performed in a dedicated strip chamber 208, distinct from the etch chamber 205, the etch chamber 205 may perform an in-situ strip process after performing the low-k dielectric etch, or the low-k repair module may perform resist strip and repair functions. For embodiments where the low-k repair module is to further perform resist/residue removal functions, the low-k repair module is further configured to include one or more plasma power sources. Depending on the embodiment, the power source may be a magnetron, RF source, or the like, as known in the art. In particular embodiments, the power source includes both a source power and a bias power to provide for an anisotropic, ion-enhanced strip process which may reduce the damage to the low-k film. Chambers which are to perform both the resist strip and low-k repair treatments are also configured to include oxidative and/or reductive process gases, such as O₂, CO₂, and/or H₂:N₂, NH₃ in addition to the vapor-phase low-k repair chemistry. In which ever chamber the resist strip is performed, the low-k dielectric thin film is exposed to damaging plasma processing at operations 105 and/or 110, leaving a damaged layer in the low-k dielectric film which displays one or more properties of a dielectric constant elevated, lower dielectric strength (e.g., higher leakage) and susceptibility to moisture absorption/retention relative to a pre-etched, “as-deposited” state.

Returning to FIG. 1A, following strip/clean of the workpiece, the workpiece is transferred from the etch chamber 205 or strip chamber 208 via the mainframe transport module 207 into a low-k repair chamber 210 to perform the remaining operations. As further illustrated in FIG. 1B, beginning with the workpiece in the low-k repair chamber 210 at operation 175, the workpiece is first heated in a pre-bake 177. An exemplary pre-bake has a duration between 120 and 180 seconds, depending on the desired temperature and process pressure which may affect heat transfer rates. Following the pre-bake 177, the workpiece is exposed to a vapor-phase chemistry at operation 179 while at the elevated temperature. An exemplary repair chemistry exposure operations 179 has a duration of 60-180 seconds, or more. Following the exposure operation 179, a post-bake operation 181 is performed after repair chemical delivery is discontinued to drive off and pump out excess species. An exemplary post-bake operation 181 has a duration of 30 and 180 seconds.

As show in FIGS. 1A and 1B, the repair method 100 depends on whether an in-vacuo UV exposure is to be performed in conjunction with an in-vacuo chemical repair treatment. If a UV treatment is to be performed in addition to the chemical treatment, then the UV exposure operation may be combined with the pre-bake 177 as UV treatment 150, and/or the UV exposure operation may be combined with the post-bake 181 as UV treatment 165, and/or the UV exposure operation may be combined with the chemical exposure operation 179 as UV treatment 170.

In one embodiment, low-k repair method 100 does not include an in-vacuo UV exposure and therefore proceeds to a chemical treatment operation 115. Generally, the chemical repair treatment operation 115 includes exposing the damaged layer of the low-k dielectric film to a vaporized chemistry to replenish the damaged layer with carbon and/or form a passivation layer in or on the low-k dielectric film. In one embodiment, a silylation process is performed at low-k treatment operation 115 to expose the damaged low-k surface to vapor-phase silylating organosilanes at a controlled process temperature and pressure enhance the kinetics of a condensation reaction between the vapor-phase organosilane and Si—OH present in the low-k dielectric film to form Si—O—Si bonds (e.g., Si—O—Si(CH₃)₃).

As depicted in FIG. 2, because the low-k repair chamber 210 is integrated with the etch chamber 205 onto the same platform 200, the workpiece is not exposed to atmosphere post-etch until operation 120, subsequent to a low-k treatment. For this reason, the low-k treatment operation 115 is referred to herein as “integrated in-vacuo,” meaning the treatment is performed without breaking vacuum between the damage inducing operation and the damage repair operation. As such, unlike ex-situ low-k dielectric repairs (e.g., ex-situ silylation), the integrated in-vacuo low-k repair process describe herein avoids exposing the low-k dielectric film damage layer to heightened levels of moisture which can react with a hydrophilic surface and have been found to form byproducts which limit the k-value recovery possible with chemical treatment.

Any vapor-phase silylation process known in the art to be capable of treating a damaged low-k dielectric layer may be employed at the low-k repair treatment operation 115. Many such liquid chemicals are commercially available, for example, through Air Liquide of Paris, France. In one embodiment, a liquid source of hexamethyldisilazane (HMDS) is provided to the workpiece in the vapor phase at operation the low-k treatment 115. In other embodiments, a liquid source of bis(dimethylamino)dimethylsilane (BDMADMS), tetramethyldisilazane (TMDS) or another aminosilane chemistry is provided to the workpiece in the vapor phase at the low-k repair treatment operation 115. In a preferred embodiment, dimethylaminotrimethylsilane (DMATMS) is provided in the vapor phase at the low-k treatment operation 115.

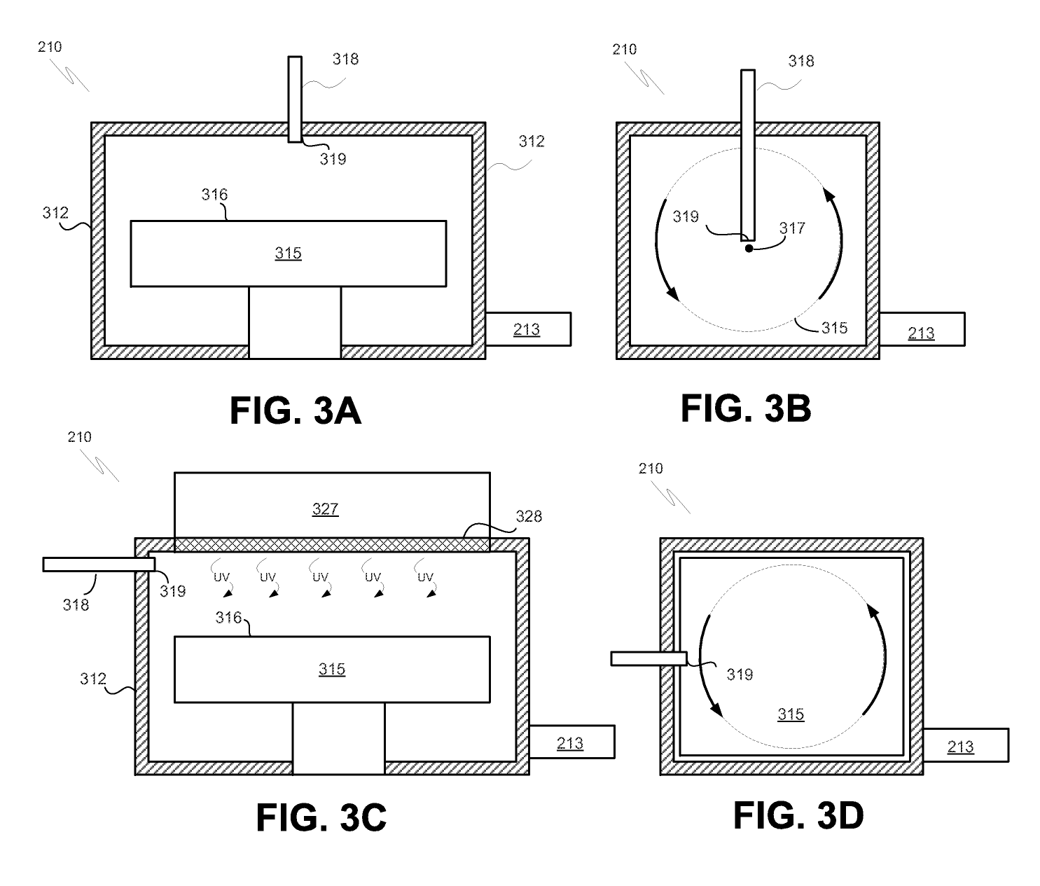

In an embodiment, the low-k repair chamber 210 is configured with a temperature controlled pedestal which may be heated and/or cooled via a control loop. FIGS. 3A and 3B depict a cross-sectional and plan view of a schematic of the low-k dielectric film repair chamber 210 in accordance with one exemplary embodiment. Pedestal 315 includes a top pedestal surface 316 upon which a workpiece is disposed during the low-k repair treatment operation 115. Resistive heating elements and/or liquid conduits may be embedded in pedestal 315 in any manner known in the art to provide a heat source/sink. In particular embodiments employing vapor-phase silylation chemistries, the pedestal 315 is heated to between approximately 100° C. and approximately 400° C. Higher temperatures have been found to assist in moisture desorption from the damage layer in the low-k dielectric film and also improves the kinetics of the silylation reactions. Higher temperatures are also believed to improve cross-linking within the repair damage layer to improve stability of the repair.

In a particular embodiment employing a vapor-phase DMATMS-based repair chemistry, the pedestal 315 is heated to between approximately 200° C. and approximately 350° C. For temperatures of 150° C. and below, repaired k-values where 2.55 or above for an as-deposited BDII film having a pre-etch k-value of 2.4. For temperatures of 200° C.-300° C. repaired k-values were below 2.5. CV measurements for the films repaired at temperatures of 150° C. and below also saturated at a voltage range of −60 to 10V while for films repaired at temperatures of 200° C.-300° C. a larger range was required (e.g., −110 to 10V for 200° C.). In a particularly advantageous embodiment employing a vapor-phase DMATMS-based repair chemistry, the pedestal 315 is heated to less than 300° C., and preferably between approximately 200° C. and approximately 225° C. for greatest stability of k-value over time following the repair process. While this sensitivity to temperature is not currently well-understood, experimental results for 200° C. treatments displayed no change in the repaired k-value over a 13 day sit time while treatments at 235° C. and 300° C. displayed increases in repaired k-value of 0.07 and 0.1, respectively, for a comparable sit time.

Referring to the embodiment depicted in FIG. 3B, the pedestal 315 is configured to rotate about a central pedestal axis 317 as the low-k repair chemistry is applied to a workpiece during the chemical repair treatment operation 115 and/or as the workpiece is exposed to UV radiation during a UV treatment operation. The rotation may improve the low-k repair uniformity across a diameter of a workpiece. The rotation may further reduce process time and thereby improve throughput through the low-k repair chamber 210 and also improve utilization of the repair chemical.

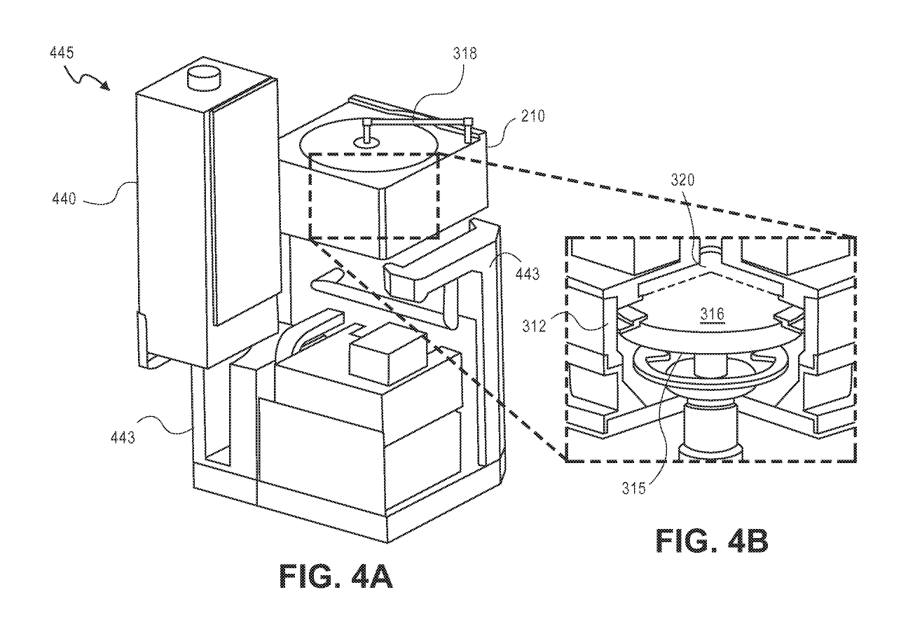

In an embodiment, as depicted in FIGS. 3A-4A, the low-k repair chamber 210 includes a gas stick 318 disposed over the pedestal 315 to provide the low-k repair chemical during the low-k repair treatment operation 115. In the exemplary embodiment depicted in FIG. 3A, the gas stick 318 couples to the low-k repair chamber 210 with an input 319 directly over the a central pedestal axis 317. It has been found central positioning of the gas stick 318 with respect to the workpiece disposed on the pedestal 315 improves both low-k repair uniformity and chemical utilization.

In a further embodiment, a showerhead 320, depicted in FIG. 4B may be disposed between the input 319 and the top pedestal surface 316. The showerhead 320 may improve gas distribution across the workpiece during the low-k repair treatment operation 115 relative to an undiffused input 319. The showerhead 320 may be made of any material known in the art for such purposes as long as the material can be adequately grounded thermally to the chamber walls 312 to prevent condensation of the vapor-phase low-k repair chemistry during the chemical repair treatment operation 115. For example, the poor thermal conductivity of quartz may disadvantageously induce condensate on the showerhead 320. In an exemplary embodiment, the showerhead 320 is of the same material as the chamber walls 312 and may be bare aluminum although other materials of similar thermal conductive may also be employed. Although the embodiment depicted in FIG. 4B includes the showerhead 320, because particular silylation reactions are self-limiting, the showerhead 320 may not be needed for good process uniformity. As such, certain embodiments do not employ the showerhead 320 and include only the input 319 to directly inject the vapor-phase low-k repair chemistry. In some embodiments lacking a showerhead 320, a small deflector (not shown) is affixed at input 319 to reduce a line-of-sight component of the flow to a workpiece. Embodiments which do not require a showerhead 320 advantageously simplify maintenance of the low-k repair chamber 210 and reduce the potential for condensate to form during the low-k repair treatment operation 115.

In an embodiment, the low-k repair chamber 210 is configured to provide a process pressure between approximately 500 mT (milliTorr) and 500 T (Torr). Practical limitations of vaporizing the low-k repair chemistry at higher pressures limit the upper bound of the process pressure, with the process pressure dependent on the vapor curve of the low-k repair chemistry chosen and the temperature at which the gas stick 318, chamber walls 312 and pedestal 315 are maintained. It has been found that higher pressures promote diffusion of the vapor-phase repair chemistry to the surface of, and into, the damage layer in low-k dielectric film. Furthermore, chemical utilization is advantageously improved at higher pressures, with the repair reaction taking a smaller quantity of chemical/workpiece. For example, a higher pressure at a given repair chemical mass flow rate will increase the residence time of the vapor-phase chemistry within the low-k repair chamber 210 and increase the efficiency of the chemistry. For this reason, embodiments include a pressure control valve that is highly responsive at the moderate vacuum levels of tens to hundreds of Torr disposed between the low-k repair chamber 210 and pump foreline 213. In certain embodiments however, the process pressure is between 3 and 5 Torr as this pressure range can be maintained with reasonably good control with the same pressure control valve capable of perform resist strip processes which are in the 300 mTorr range with gas flow rates on the same order as the carrier flow rate utilized in the chemical treatment.

In an embodiment, the chamber walls 312 and gas stick 318 are heated and controlled to an elevated temperature to prevent condensation of the low-k repair chemistry at the upstream pressures associated with the process pressure utilized to achieve a particular partial pressure of the vapor-phase low-k repair chemistry. For example, 21° C. is to achieve a 50 Torr partial pressure of DMATMS while 75° C. is required to achieve a 50 Torr partial pressure of BDMSDMA. In a particular embodiment, the gas stick 318 is heated from the input 319 upstream to a junction where a liquid chemical is vaporized into a carrier gas. The gas stick 318 and chamber walls are heated to a temperature dependent on the low-k repair chemistry employed and the process pressure. In particular embodiments employing HMDS or DMATMS, the chamber walls 312 (and any showerhead thermally grounded thereto) are heated to at least 60° C. and preferably 70° C. or greater. In further embodiments, the chamber walls 312 the gas stick 318 and valving there between is heated to 60° C.-150° C., and preferably between 100° C. and 110° C., as the pressure increments up stream toward the vaporizer.

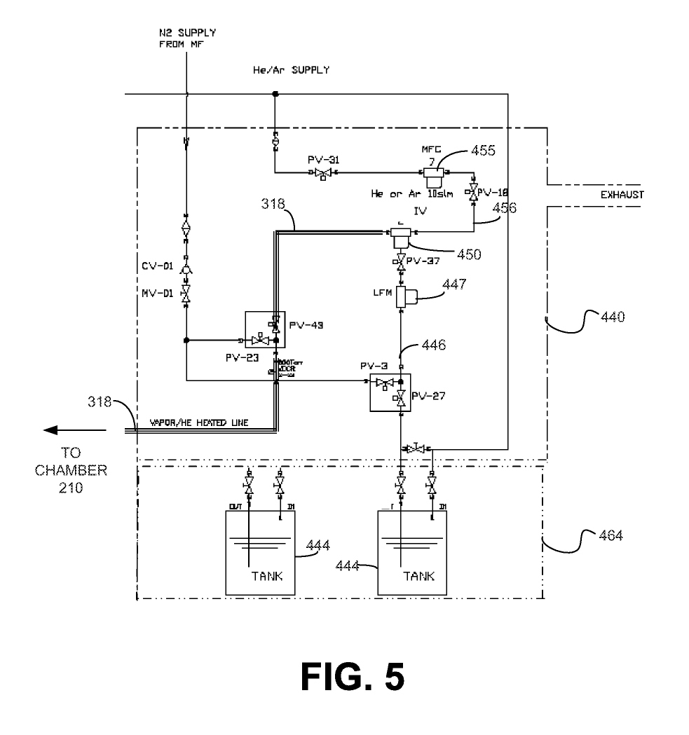

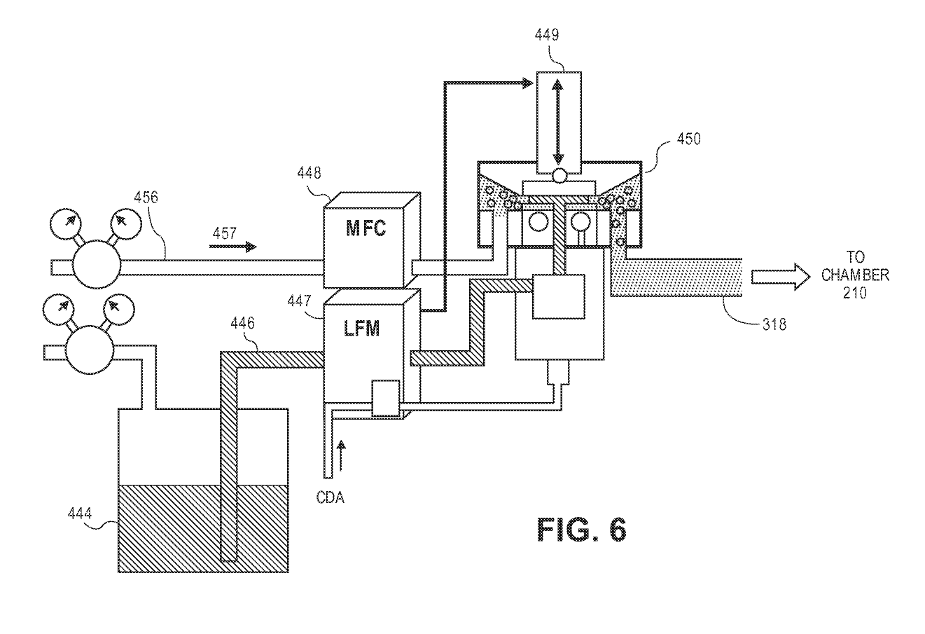

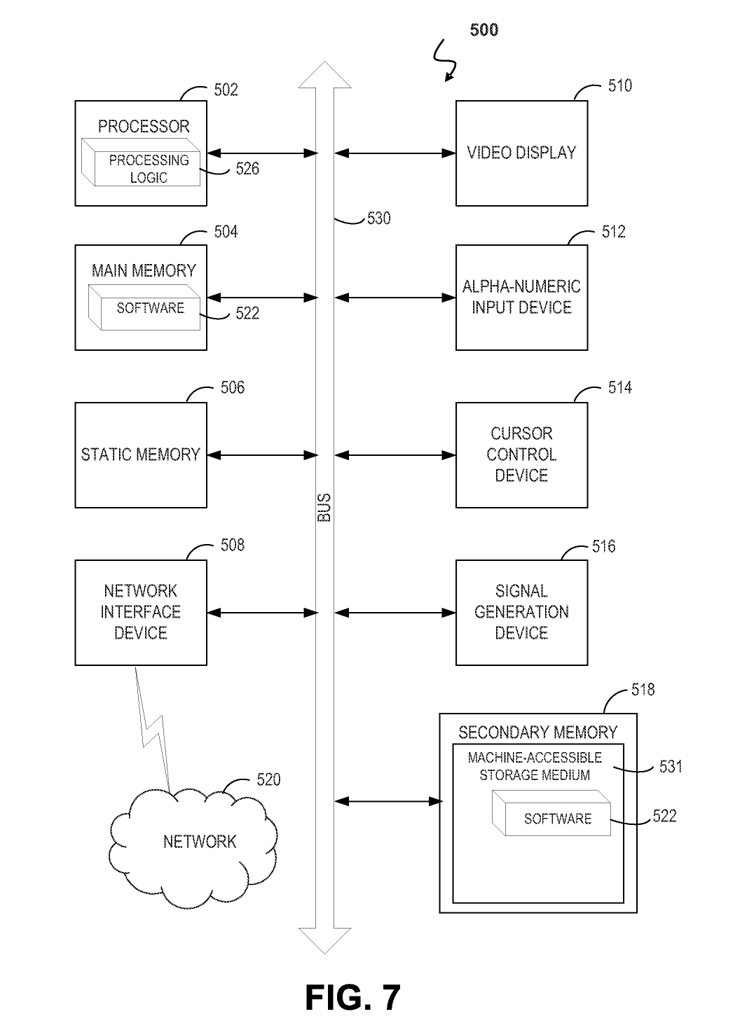

In an embodiment, as depicted in FIG. 2 and FIG. 4A, a vapor cabinet 440 that includes a vaporizer is mounted onto the module 445 and is mechanically coupled to the low-k repair chamber by a support frame 443. With the vapor cabinet mounted directly onto the module 445, heated line distances are advantageously reduced and standardized for the low-k repair chamber 210 to improve chamber matching relative to systems which do not have the vapor cabinet integrated onto the same module as the chamber. As further illustrated schematically in FIG. 5, liquid low-k repair chemical is provided in tanks 444 which may be stored in a sub-fab container 464. A liquid line 446 couples the tanks 444 to the vaporizer via a liquid flow meter (LFM) 447. Although a nitrogen bubbler as well as any other vaporizer known in the art may be utilized, in a particularly advantageous embodiment, a precision liquid injection system (PLIS) is employed which links control of the both LFM 447 and a carrier gas MFC 455 to actuation of a flash vaporizer 450 to achieve a particular process vapor-phase flow rate at the gas stick 318. As depicted in FIG. 5, each of the flash vaporizer 450, the carrier gas MFC 455 and LFM 447 are contained within the vapor cabinet 440. The exemplary injection system depicted in FIG. 5 may be provisioned using components commercially available through Horiba Stec, Co., Ltd. of Kyoto, Japan.

The carrier gas employed to deliver the vapor-phase low-k chemistry may be any inert species. Certain carrier gas embodiments are substantially free of nitrogen to avoid nitrogen doping of the low-k dielectric film under repair. In a particularly embodiments, the carrier gas employed is either helium (He) or argon (Ar). Advantageous embodiments employing He provides improved thermal conducting properties relative to conventional bubbler configurations employing a nitrogen gas (N₂) or Ar carrier. Specifically, the presence of a He-rich environment within the low-k repair chamber 210 provides good thermal conduction between a workpiece and the top pedestal surface 316. He enables prompt backside heat transfer even at process pressures in the low Torr (3-5 Torr) pressure regimes. Use of He can therefore avoid complications associated with clamping of the workpiece to the pedestal 315 and provisioning specific backside heat transfer media for process pressures which can be controlled at the most advantageously high repair chemical partial pressures and low repair chemical flow rates. Also noteworthy is that vapor curves for low-k repair chemistries in He, such as HMDS and DMATMS, etc. are characterized by advantageously low condensation temperatures. In certain embodiments therefore, the MFC 455 is calibrated He.

In an embodiment, the carrier gas 457 may be heated in the line 456 upstream of the flash vaporizer 450 to increase the vaporization rate of the liquid low-k repair chemistry. The flow rate of the carrier gas is dependent on the vapor pressure of the liquid low-k repair chemistry and may be anywhere between approximately 100 sccm and 20 slm, and preferably between 1 and 10 slm, while the liquid low-k repair chemistry may have a flow rate in the range of 100 mg/min to 5 g/min, depending on the partial pressures achievable for the particular chemistry, temperatures, and process pressures. It has been found that for DMATMS embodiments, flows rates between 0.5 g/min and 1 g/min in He carrier flow rates of 2 slm perform as well as flow rates as high as 5 g/min with the response on partial pressure being weaker than the responses to process temperature and process time.

Returning to FIG. 1A, following the low-k repair treatment operation 115, the workpiece may be returned to the indexer 206B via the mainframe transport module 207 and vented to atmosphere to complete the low-k repair method 100. As so illustrated, a low-k dielectric film damage layer is repaired without breaking vacuum between the damage event and the repair event to provide an integrated in-vacuo low-k dielectric etch/strip/repair apparatus and method.

As further illustrated in FIG. 1A, embodiments of the present invention utilize an integrated, in-vacuo UV exposure in addition to, or as part of the integrated low-k repair. Generally, it has been found UV exposure of the workpiece, and in particular of the low-k dielectric damage layer can provide improved levels of repair and repair stability as compared with treatments in absence of UV. Depending on the embodiment, the UV exposure operation 150 may be performed in the etch chamber 205, strip chamber 208, mainframe transport module 207 or low-k repair chamber 210. However, because it has been found that the application of UV in conjunction with thermal treatment is advantageous, the LTV exposure is preferably performed by the low-k repair chamber 210. Depending on the embodiment, a UV exposure may be performed prior to, during, or subsequent to, low-k repair chemical treatments as depicted in FIG. 1B.

In one embodiment, a UV exposure is performed prior to a low-k repair chemical treatment (e.g., during the pre-bake 177 as depicted in FIG. 1B). At operation 150, the workpiece is exposed to UV radiation in the 200-280 nm wavelength range and preferably between 200 nm and 250 nm. Such a wavelength range ensures Si—C bonds are not detrimentally affected while still promoting a condensation reaction converting Si—OH in the damage layer to Si—O—Si. The 200-250 nm range may also promote cross-linking and elimination of dangling bonds.

With the UV exposure operation 150 following the etch operation 105 and strip operation 110, moisture present in the damage layer from either of these operations may be driven off to a desired level depending on the combination of both pedestal temperature and UV intensity (dosage). An exemplary intensity at 250 nm is approximately 400WPI. The pedestal 315 may be heated to a temperature, such as 200° C., while a particular intensity and wavelength of UV light is applied to the workpiece. The UV exposure may be anywhere from 5 seconds to the full duration of the pre-bake 177 (e.g., 120 seconds or more) with the preferred embodiment employing a UV exposure for the last 30 seconds of the pre-bake operation to allow sufficient time for the workpiece to reach the pedestal temperature.

Following the UV exposure operation 150, method 100 proceeds to a low-k repair treatment operation 155. Any of the processes and conditions described for the low-k repair treatment operation 115 may be utilized for the low-k repair treatment operation 155. Temperature and UV parameters may then be optimized between the operations 150 and 155 to best achieve low-k repair. In one particular embodiment, a workpiece is first loaded into the low-k repair chamber 210, a carrier gas, such as He, is provided, a process pressure setpoint of 3-5 Torr achieved and the workpiece allowed to approach the pedestal temperature of 200-300° C., and UV radiation introduced for 30 seconds while the workpiece is on the pedestal 315. Subsequently the UV source may be turned off and a silylation process performed at operation 155 by achieving the repair treatment process temperature and adding the low-k repair chemistry to achieve the desired process pressure and chemistry partial pressure(s).

To provide the UV radiation, embodiments of the low-k repair chamber 210 include a UV source 327, as depicted in FIG. 3C. The UV source 327 may be any lamp or discharge known in the art to provide the wavelengths and intensity ranges described elsewhere herein. In a particular embodiment, the UV source 327 is external of the chamber walls 312 and the UV radiation is transmitted to the workpiece through a UV transparent wall 328. The UV transparent wall 328 may be thermally grounded to the chamber walls 312 to prevent low-k repair chemical condensation on the UV transparent wall 328. However, in other embodiments, the UV transparent wall 328 is a material with only a moderate thermal conductivity, such as quartz. For embodiments employing a quartz UV transparent wall 328 energy coupled from the UV source (e.g., IR wavelengths emitted from UV source, UV absorbers present in the quartz, etc.), conduction from chamber walls 312, or radiation from pedestal 315, and chamber walls 312 is relied upon to keep the quartz sufficient warm to avoid condensation of a low-k repair chemical. As such, embodiments with chamber walls heated to between 100 and 110° C. are further advantageous.

As also depicted in FIG. 3D, the gas stick 318 may be routed to input a low-k repair chemical at a location proximate to an outer perimeter of the pedestal 315 rather than above the central pedestal axis 317 (FIG. 3B) to prevent shadowing of the UV radiation. As further depicted in FIG. 3D, particular embodiments utilize a rotating pedestal 315 to improve uniformity of the repair chemical and/or UV radiation. Such embodiments may be particularly advantageous where the input 319 is asymmetrically disposed relative to the workpiece (e.g., a pedestal perimeter) or the gas stick 318 shadows a portion of the workpiece from UV radiation.

Following operation 155, or if the UV exposure is not performed prior to a low-k repair treatment, the method 100 depends on if a UV exposure is to be performed last. Performing a UV treatment subsequent to the low-k repair treatment offers the advantages of providing some moisture (e.g., moisture that would otherwise be lost via the UV treatment) in the damaged film to promote a condensation reaction during the film repair while still providing and energy source to promote crosslinking, termination of dangling bonds, etc. within the repaired low-k dielectric layer as the excess repair chemical is bake off/pump out during the post bake operation 181 (FIG. 1B). The UV-last exposure may also eliminate end groups from silylation by-products to increase the density of the Si—O network in the repair layer. For embodiments where the UV exposure is to be performed last, if a low-k repair has not yet been performed, then the method 100 proceeds from the resist strip operation 110 to a chemical repair operation 160 where any of the processes with any of the conditions described for the low-k repair treatment operation 115 are performed. The workpiece is then exposed to UV radiation at the UV treatment operation 165. Any of the process conditions previously described for the UV exposure may be provided at operation 165.

In alternative embodiments, where the UV exposure is to be performed last and a chemical repair has already been performed (e.g., for a sequence where a first UV exposure is provided at operation 150, then a chemical repair treatment is performed at operation 155), method 100 bypasses the chemical repair treatment 160 and proceeds from the chemical repair treatment 155 to the UV exposure operation 165 so that a UV exposure is both before and after the low-k repair treatment operation 155. With the last UV exposure performed, the method 100 completes with the workpiece being unloaded from the platform 200 and venting of the workpiece to atmosphere.

In another embodiment depicted in FIGS. 1A and 1B, UV exposure is provided concurrently with performance of a low-k repair treatment at operation 170. At operation 170, any of the UV conditions described for the UV treatment operations 150 and 165 may be provided concurrently with any of the chemical repair conditions described for chemical treatment operation 115. In such embodiments, UV radiation may provide sufficient energy to break bonds in the vapor-phase repair chemical. For example, relatively weak C═O double bonds may be severed by the UV radiation applied during application of certain silylating chemistries. Concurrent UV radiation may therefore assist in the actual repair of the low-k dielectric damage layer. In certain embodiments, UV assisted deposition may be performed at operation 170 to seal pores of damaged and/or highly porous low-k dielectrics. For such embodiments, the low-k repair chamber 210 further includes provisions for chamber cleans (e.g., halogen and/or oxidizer gas sources, microwave or RF plasma energy sources, etc.), as known in the art, to remove deposition residues from the chamber walls.

Any of the methods described herein may be automatically executed and controlled by components of the platform 200 in response to commands issued by a computer processing system executing instructions stored on a computer-readable medium. FIG. 5 illustrates a diagrammatic representation of a machine in the exemplary form of a computer system 500 which may be utilized to perform the temperature control operations described herein. In one embodiment, the computer system 500 may be provisioned as the controller of one or more of the modules in the platform 200. The machine may be a personal computer (PC) or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies discussed herein.

The exemplary computer system 500 includes a processor 502, a main memory 504 (e.g., read-only memory (ROM), flash memory, dynamic random access memory (DRAM) such as synchronous DRAM (SDRAM) or Rambus DRAM (RDRAM), etc.), a static memory 506 (e.g., flash memory, static random access memory (SRAM), etc.), and a secondary memory 518 (e.g., a data storage device), which communicate with each other via a bus 530.

The processor 502 represents one or more general-purpose processing devices such as a microprocessor, central processing unit, or the like. More particularly, the processor 502 may be a complex instruction set computing (CISC) microprocessor, reduced instruction set computing (RISC) microprocessor, very long instruction word (VLIW) microprocessor, processor implementing other instruction sets, or processors implementing a combination of instruction sets. The processor 502 may also be one or more special-purpose processing devices such as an application specific integrated circuit (ASIC), a field programmable gate array (FPGA), a digital signal processor (DSP), network processor, or the like. The processor 502 is configured to execute the processing logic 526 for performing the temperature control operations discussed elsewhere herein.

The computer system 500 may further include a network interface device 508. The computer system 500 also may include a video display unit 510 (e.g., a liquid crystal display (LCD) or a cathode ray tube (CRT)), an alphanumeric input device 512 (e.g., a keyboard), a cursor control device 514 (e.g., a mouse), and a signal generation device 516 (e.g., a speaker).

The secondary memory 518 may include a machine-accessible storage medium (or more specifically a computer-readable storage medium) 531 on which is stored one or more sets of instructions (e.g., software 522) embodying any one or more of the temperature control algorithms described herein. The software 522 may also reside, completely or at least partially, within the main memory 504 and/or within the processor 502 during execution thereof by the computer system 500, the main memory 504 and the processor 502 also constituting machine-readable storage media. The software 522 may further be transmitted or received over a network 520 via the network interface device 508.

The machine-accessible storage medium 531 may further be used to store a set of instructions for execution by a processing system and that cause the system to perform any one or more of the temperature control algorithms described herein. Embodiments of the present invention may further be provided as a computer program product, or software that may include a machine-readable medium having stored thereon instructions, which may be used to program a computer system (or other electronic devices) to control a plasma processing chamber temperature according to the present invention as described elsewhere herein. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, and flash memory devices, etc.

What is claimed is:

1. A vacuum chamber module for repair of plasma-damaged low-k dielectric thin films, the vacuum chamber module comprising:
a vacuum chamber including a pedestal to support a workpiece, the pedestal surrounded by chamber walls;
a vapor cabinet mechanically coupled to the vacuum chamber by a support frame, the vapor cabinet containing:
a flash vaporizer coupled to a carrier gas mass flow controller (MFC) and coupled to a low-k repair liquid chemical flow meter (LFM); and
a gas stick coupling the flash vaporizer to the low-k repair chamber to inject a vapor-phase low-k repair chemical into the repair chamber, wherein the pedestal, the chamber walls, and the gas stick are controllable to a temperature of at least 60° C.

2. The vacuum chamber module as in claim 1, further comprising a showerhead disposed between the pedestal and the gas stick outlet, wherein the showerhead is thermally grounded to the chamber walls to be passively heated only by conduction with the chamber walls.

3. The vacuum chamber module as in claim 2, wherein the showerhead comprises bare aluminum.

4. The vacuum chamber module as in claim 1, further comprising a UV source to emit in the 200-280 nm wavelength range, wherein UV source is external to the chamber walls with a chamber wall portion between the UV source and the pedestal is UV transparent.

5. The vacuum chamber module as in claim 4, wherein the UV source has an'intensity of at least 400 watts per inch (WPI).

6. The vacuum chamber module as in claim 4, wherein the UV transparent chamber wall is disposed above the pedestal and wherein the gas stick is coupled to a chamber wall proximate to an outer perimeter of the pedestal.

7. The vacuum chamber module as in claim 6, wherein the pedestal is rotatable about a central axis of the pedestal.

8. The vacuum chamber module as in claim 1, wherein the MFC is calibrated for Helium (He).

9. The vacuum chamber module as in claim 1, wherein the chamber is controllable to a pressure between 500 mTorr and 500 Torr, wherein the pedestal is controllable to a temperature between 300-350° C., and wherein the gas stick and chamber walls are controllable to a temperature of 100-110° C.

10. The vacuum chamber module as in claim 1, further comprising a plasma power source to generate a plasma within the vacuum chamber.

11. A plasma processing platform for integrated in-vacuo repair of plasma-damaged low-k dielectric thin films, the platform comprising:
a plasma etch chamber module; and
a low-k repair chamber module coupled to the plasma etch chamber module by a mainframe transport module to transport a workpiece etched in the plasma etch chamber module to the low-k repair chamber under vacuum, wherein the low-k repair chamber further comprises:
a vacuum chamber including a pedestal to support a workpiece, the pedestal surrounded by chamber walls;
a vapor cabinet mechanically coupled to the vacuum chamber by a support frame, the vapor cabinet containing a flash vaporizer, a carrier gas mass flow controller (MFC) coupled to the flash vaporizer, and a low-k repair liquid chemical flow meter (LFM) coupled to the flash vaporizer; and
a gas stick coupling the flash vaporizer to the low-k repair chamber to inject a vapor-phase low-k repair chemical into the repair chamber, wherein the pedestal, the chamber walls, and the gas stick are controllable to a temperature of at least 60° C.

12. The plasma processing platform as in claim 11, wherein the low-k repair chamber includes a plasma power source to generate a plasma within the low-k repair chamber prior

13. The plasma processing platform as in claim 12, further comprising plasma resist strip chamber coupled to the transport module to remove photo resist from a workpiece after a plasma etch process and prior to a low-k repair process without breaking vacuum.

14. A method for repair of plasma-damaged low-k dielectric thin films, the method comprising:
loading a workpiece into a vacuum processing platform, the workpiece including a low-k dielectric film having a dielectric constant below 2.5;
exposing the low-k film to a plasma in an etch chamber of the platform;
transporting, under vacuum, the workpiece from the etch chamber to a low-k repair chamber of the platform;
performing a UV treatment of the low-k dielectric film by exposing the workpiece to UV radiation source external to the low-k repair chamber;
performing a silylation treatment of the low-k dielectric film by exposing the workpiece to a vapor phase low-k repair chemistry in the low-k repair chamber; and
unloading the workpiece from the vacuum processing platform.

15. The method as in claim 14, wherein the UV treatment is performed prior to the silylation treatment.

16. The method as in claim 15, wherein the UV treatment comprises exposing the workpiece to at least 400 watts per inch (WPI) of UV radiation in the 200-280 nm wavelength range for at least 20 seconds while the workpiece is heated to 200-225° C.

17. The methods in claim 14, wherein the vapor phase low-k repair chemistry comprises dimethylaminotrimethylsilane (DMATMS).

18. The method as in claim 17, wherein the vapor phase low-k repair chemistry comprises a carrier gas of helium (He) and wherein the DMATMS is provided at 0.5-1.0 gm/min at a pressure of 3-5 Torr for between 2 and 3 minutes.

19. The method as in claim 14, further comprising:
performing an ashing process in the low-k repair chamber prior to performing the UV treatment, wherein the ashing process comprises exposing the workpiece to a plasma of at least one oxidizing process gas.

20. The method as in claim 19, wherein the oxidizing process gas comprises CO₂.

21. The method as in claim 19, wherein the ashing process further comprises energizing the plasma with a bias power of at least 100 watts.

22. The method as in claim 14, wherein the low-k dielectric film comprises a PECVD organosilicate glass (OSG).
